(19) United States
(12) Patent Application Publication
(10) Pub. No.: US 2026/0005177 A1
(43) Pub. Date: Jan. 1, 2026

(54) ELECTRONIC DEVICE AND FLIP-CHIP DIE ASSEMBLY WITH PREFORMED UNDERFILL AND STUD BUMPS

(71) Applicant: Texas Instruments Incorporated, Dallas, TX (US)

(72) Inventors: How Kiat Liew, Kuala Lumpur (MY); Amirun Hamizan Bin Budizaman, Hulu Langat (MY); Ahmad Ridzuan Bin Abd Rahman, Sepang (MY)

(21) Appl. No.: 18/758,336

(22) Filed: Jun. 28, 2024

(51) Int. Cl. H01L 23/00; H01L 23/31

(52) U.S. Cl. CPC H01L 24/16; H01L 23/3135; H01L 24/13; H01L 24/27; H01L 24/29; H01L 24/32; H01L 24/73; H01L 24/81; H01L 2224/13124; H01L 2224/13139; H01L 2224/13147; H01L 2224/16227; H01L 2224/2732; H01L 2224/2919; H01L 2224/73204; H01L 2224/81205; H01L 2924/3511; H01L 2924/3512

(57) ABSTRACT

An electronic device includes a flip-chip die assembly having a semiconductor die and a preformed underfill, the semiconductor die having conductive bond pads spaced apart from one another along a side of the semiconductor die and conductive stud bumps having proximal ends on respective ones of the conductive bond pads and distal ends extending outward from the side, and the preformed underfill extending on a portion of the side between the conductive stud bumps and exposing the distal ends of the conductive stud bumps.

### BACKGROUND

Flip-chip technology helps reduce electronic device size and increase circuit density. Processed wafers are provided with solder bumps for electrical connections and individual dies are then separated from the wafer for flip-chip bonding to a board, substrate or lead frame by high temperature reflowing of the solder bumps. An underfill material is then injected under each individual die to lower die stress, control die warpage and increase reliability. However, flip-chip soldering with conventional gold, tin and/or copper bumps (e.g., CuSn, Sn, Au) requires high temperature reflow such as 260 degrees C. or more, which may adversely affect the die material and/or joint strength through oxidation and can lead to strip warpage during manufacturing. Moreover, the underfilling process is slow and complicated, leading to increased production costs. Underfill material is dispensed under each individual die and a capillary effect ideally fills the gaps between the flip-chip die and the underlying structure between the bumps, but underfill voids can occur especially for high bump density and small pitch bump designs.

### SUMMARY

In one aspect, an electronic device includes a flip-chip die assembly with a semiconductor die and a preformed underfill, the semiconductor die having conductive bond pads spaced apart from one another along a side of the semiconductor die and conductive stud bumps having proximal ends on respective ones of the conductive bond pads and distal ends extending outward from the side, and the preformed underfill extends on a portion of the side between the conductive stud bumps and exposing the distal ends of the conductive stud bumps.

In another aspect, a system includes a circuit board having a conductive trace and an electronic device comprising a flip-chip die assembly and a conductive lead coupled to the conductive trace, the flip-chip die assembly having a semiconductor die and a preformed underfill. The semiconductor die has conductive bond pads spaced apart from one another along a side of the semiconductor die and conductive stud bumps having proximal ends on respective ones of the conductive bond pads and distal ends extending outward from the side. The preformed underfill extends on a portion of the side between the conductive stud bumps and exposes the distal ends of the conductive stud bumps.

In a further aspect, a method includes forming conductive stud bumps having proximal ends on respective conductive bond pads along a side of a semiconductor wafer and distal ends extending outward from the side, forming an underfill on a portion of the side between the conductive stud bumps and exposing the distal ends of the conductive stud bumps, separating a semiconductor die from the semiconductor wafer, the semiconductor die including the conductive stud bumps and the underfill, and flip-chip bonding the distal ends of the conductive stud bumps to a substrate or lead frame with conductive features, the distal ends of the conductive stud bumps engaging respective ones of the conductive features of the substrate or lead frame.

### BRIEF DESCRIPTION OF THE DRAWINGS

FIG. 1 is a partial sectional side elevation view of an electronic device including a flip-chip die assembly with a preformed underfill on a package substrate.

FIG. 1A is a partial sectional side elevation view of another electronic device including a flip-chip die assembly with a preformed underfill with a molded package structure on a package substrate.

FIG. 1B is a partial sectional side elevation view of another electronic device including a flip-chip die assembly with a preformed underfill with a molded package structure on a lead frame.

FIG. 2 is a flow diagram of a method of making an electronic device.

FIGS. 3-10 are partial sectional side elevation views of the electronic device of FIG. 1B undergoing fabrication processing according to an implementation of the method of FIG. 2.

### DETAILED DESCRIPTION

In the drawings, like reference numerals refer to like elements throughout, and the various features are not necessarily drawn to scale. Also, the term “couple” or “couples” includes indirect or direct electrical or mechanical connection or combinations thereof. For example, if a first device couples to or is coupled with a second device, that connection may be through a direct electrical connection, or through an indirect electrical connection via one or more intervening devices and connections. One or more operational characteristics of various circuits, systems and/or components are hereinafter described in the context of functions which in some cases result from configuration and/or interconnection of various structures when circuitry is powered and operating. In the following discussion and in the claims, the terms “including”, “includes”, “having”, “has”, “with”, or variants thereof are intended to be inclusive in a manner similar to the term “comprising”, and thus should be interpreted to mean “including, but not limited to”.

Unless otherwise stated, “about,” “approximately,” or “substantially” preceding a value means +/−10 percent of the stated value. One or more operational characteristics of various circuits, systems and/or components are hereinafter described in the context of functions which in some cases result from configuration and/or interconnection of various structures when circuitry is powered and operating. One or more structures, features, aspects, components, etc., may be referred to herein as first, second, third, etc., such as first and second terminals, first, second, and third, wells, etc., for ease of description in connection with a particular drawing, where such are not to be construed as limiting with respect to the claims. Various structures and methods of the present disclosure may be beneficially applied to an electronic device or apparatus such as an integrated circuit and to manufacturing electronic devices. While such examples may be expected to provide various improvements, no particular result is a requirement of the present disclosure unless explicitly recited in a particular claim.

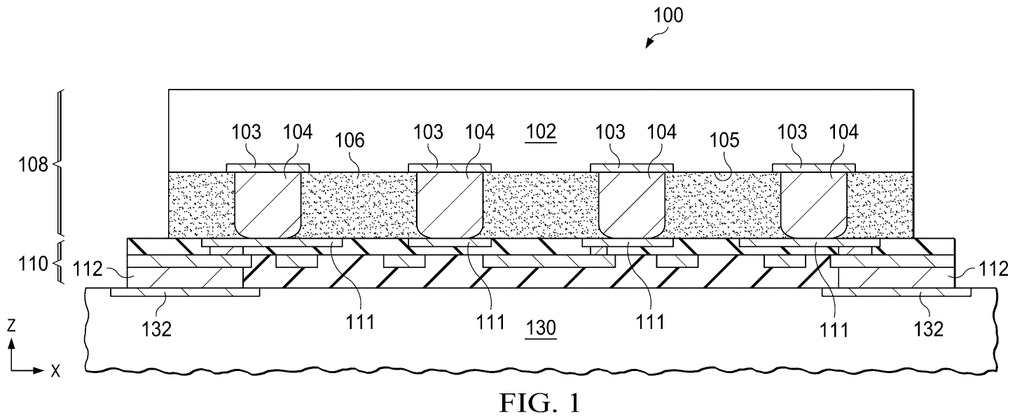

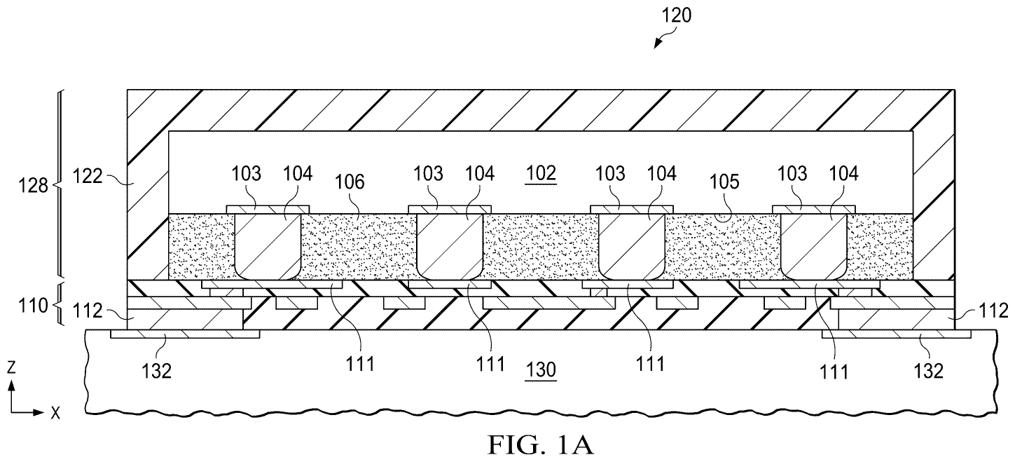

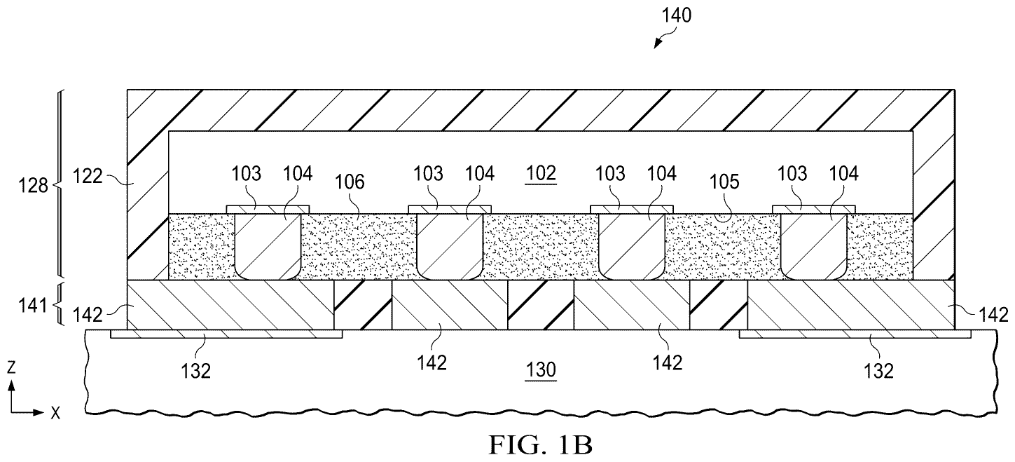

FIG. 1 shows an example electronic device 100 with a flip-chip die assembly 108 that includes a semiconductor die 102 having conductive bond pads 103 that are laterally spaced apart from one another (e.g., along the X direction in the illustrated orientation). The conductive bond pads 103 are positioned another along a front (e.g., bottom) side 105 of the semiconductor die 102. The semiconductor die 102 also has conductive stud bumps 104 with upper or proximal ends on respective ones of the conductive bond pads 103, and lower or distal ends extending outward from the side 105 along the indicated Z direction in the illustrated orientation. In the illustrated example, the conductive stud bumps 104 are or include electrically conductive metal, such as silver, copper, aluminum, etc., or combinations or alloys thereof. For example, the stud bumps 104 can be formed by wire bonding equipment (not shown), with the stud bumps 104 including material used in bond wires in electronic device manufacturing.

The flip-chip die assembly 108 also includes a preformed underfill 106 that extends on a portion of the side 105 between the conductive stud bumps 104 and exposes the distal ends of the conductive stud bumps 104. In one example, the preformed underfill 106 is or includes an electrically non-conductive die attach adhesive, such as a non-conductive epoxy. In another example, the preformed underfill 106 is or includes a laminate die attach film (DAF). Other preformed underfill materials can be used in other implementations, which promote lower die stress, control die warpage and increase reliability, while facilitating complete filling of the space between the lower side 105 of the semiconductor die 102 and structure to which the flip-chip die assembly 108 is subsequently attached (e.g., PCB, single or multilevel package substrate, lead frame, etc.) with few or no voids. In one example, the preformed underfill 106 is or includes wafer back coating epoxy material with relatively low viscosity (e.g., approximately 7.5 Pascal-seconds or Pa·s) compared to previously used underfill material with higher viscosity in reliance on the capillary effect to fill voids under the surface of an attached die (e.g., approximately 55 Pa·s).

The preformed underfill 106 allows bonding of the exposed distal ends of the conductive stud bumps 104 to an attached structure and helps reduce manufacturing cost and improved filling with minimal or no voids through formation during wafer processing prior to die singulation. In addition, the distal ends of the conductive stud bumps 104 can be adhered to an attached structure by low temperature direct surface metal-to-metal bonding, for example, a low temperature ultrasonic flip-chip bonding (e.g., ultrasonic welding) or other low temperature process, such as thermosonic or thermocompression bonding. This helps reduce or avoid oxidation and/or strip warpage during fabrication processing compared to higher temperature solder reflow operations.

In the illustrated example, the flip-chip die assembly 108 is bonded to a package substrate 110. The substrate 110 has conductive features 111 along a top side of the substrate 110, such as pads or traces that are or include metal such as copper, aluminum, etc. The distal ends of the conductive stud bumps 104 engage respective ones of the conductive features 111 of the substrate 110 by direct contact. In one example, the distal ends of the conductive stud bumps 104 directly contact the respective ones of the conductive features 111 of the substrate 110 without any intervening solder. In one implementation, the distal ends of the conductive stud bumps 104 of the flip-chip die assembly 108 are bonded to the respective ones of the conductive features 111 of the substrate 110 by respective surface metal-to-metal bonds, for example, by ultrasonic or other type of welding to form mechanical and electrical connections with metal-to-metal bonds.

The substrate 110 in one example is a multilayer or multilevel package substrate with conductive routing features in multiple levels (e.g., conductive metal traces, conductive metal vias, etc.) to electrically route signals from the semiconductor die 102 and circuitry thereof through the bond pads 103 and the conductive metal stud bumps 104 to conductive metal leads 112 along the bottom side of the substrate 110. In other examples, the flip-chip die assembly 108 is bonded to a single level package substrate (not shown), or to a multilevel package substrate having more or fewer layers or levels. In a further example, the flip-chip die assembly 108 is bonded to a lead frame (e.g., FIG. 1B below). In another implementation, the flip-chip die assembly 108 can be directly bonded to a host system, such as a printed circuit board, for example, by metal-to-metal bonds between the distal ends of the conductive metal stud bumps 104 to conductive metal circuit board features (e.g., pads, traces, etc).

The preformed underfill 106 extends between the side 105 of the semiconductor die 102 to the top side of the substrate 110 and provides fully or substantially void-free filling to fill in the gaps between the conductive metal stud bumps 104. The void-free preformed underfill 106 advantageously facilitates reduced spacing or pitch distance between adjacent conductive metal stud bumps 104 to help increase circuit and I/O density of the electronic device 100. In addition, the preformed underfill 106 provides significant reduction in manufacturing time, complexity and cost compared to dispensing underfill material under each individual die after circuit board mounting using capillary effects that may not adequately fill the gaps between a flip-chip die and the underlying structure between solder bumps, particularly for high stud bump density and small pitch stud bump device designs.

The electronic device 100 is illustrated in a system application in FIG. 1, with the electronic device 100 mounted to a circuit board 130 having conductive traces 132 or other conductive metal interconnection features. The electronic device 100 in this example has conductive leads 112 along portions of the bottom side of the multilevel package substrate 110 that are coupled to respective conductive traces 132, for example, by solder connections. In another example, the electronic device 100 can be installed in a socket (not shown) of the host circuit board 130 with the conductive leads 112 engaging corresponding socket terminals to form electrical connections between circuitry or components of the electronic device 100 and a host circuit of the circuit board 130.

FIG. 1A shows another example electronic device 120 including a flip-chip die assembly 128 with a preformed underfill 106. In one example, the electronic device 120 in FIG. 1A has one or more structures and features 102-106 and 110-112 that can be the same or similar to the similarly numbered structures and features illustrated and described above in connection with the electronic device 100 of FIG. 1, except as noted hereinafter. The flip-chip die assembly 128 in this example includes the semiconductor die 102 with the conductive bond pads 103 and conductive metal stud bumps 104 generally as described above. In addition, the electronic device 120 has a molded package structure 122. The molded package structure 122 encloses at least a portion of the semiconductor die 102 and a portion of the upper or top side of the multilevel package substrate 110. In the illustrated implementation, the molded package structure 122 has lateral sides that are generally coplanar with lateral sides of the multilevel package substrate 110, although not a requirement of all possible implementations.

FIG. 1B shows yet another example electronic device 140 that has a flip-chip die assembly 128 with a preformed underfill 106 and a molded package structure 122, including structures and features 102-106, 122, and 128 that can be the same or similar to the similarly numbered structures and features illustrated and described above in connection with the electronic devices 100 and 120 of FIGS. 1 and 1A, except as noted hereinafter. The flip-chip die assembly 128 of the electronic device 140 in FIG. 1B is attached by flip-chip bonding to a lead frame 141 having conductive leads 142. In the illustrated implementation, the flip-chip die assembly 128 has a molded package structure 122 that encloses the semiconductor die 102 and the lateral sides of the preformed underfill 106 and extends to portions of the top side of the lead frame leads 142. In this example, the molded package structure 122 can be formed prior to separation of the semiconductor die 102 and the preformed underfill 106 from a processed wafer. In another implementation (not shown), the molded package structure 122 can be formed after installation of the flip-chip die assembly 128 onto the lead frame 141, and the molded package structure 122 can be formed so as to extend between adjacent ones of the leads 142 of the lead frame 141, although not a requirement of all possible implementations.

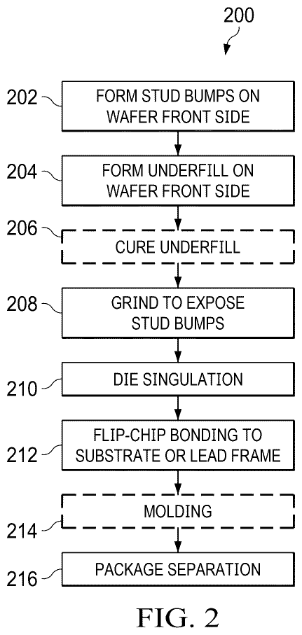

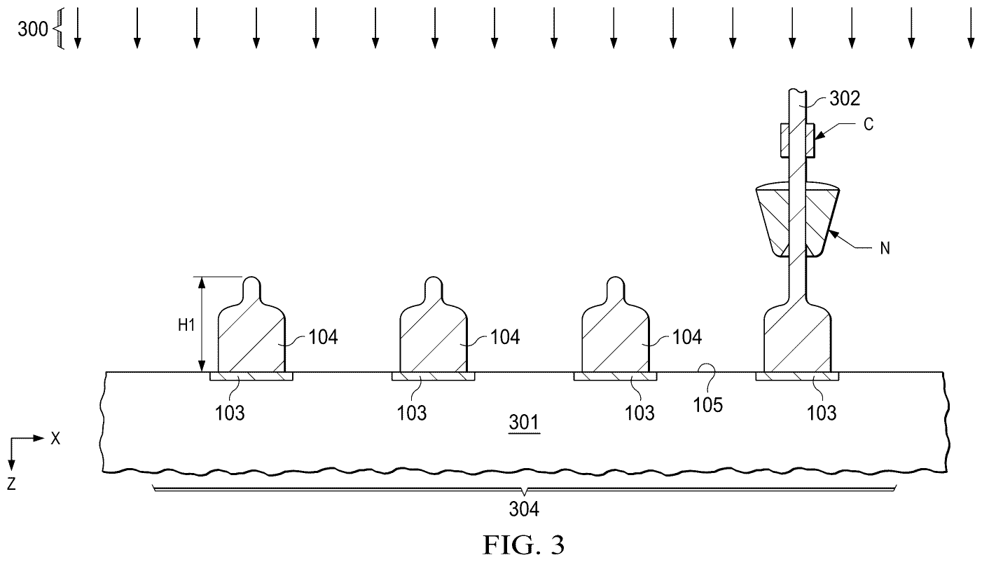

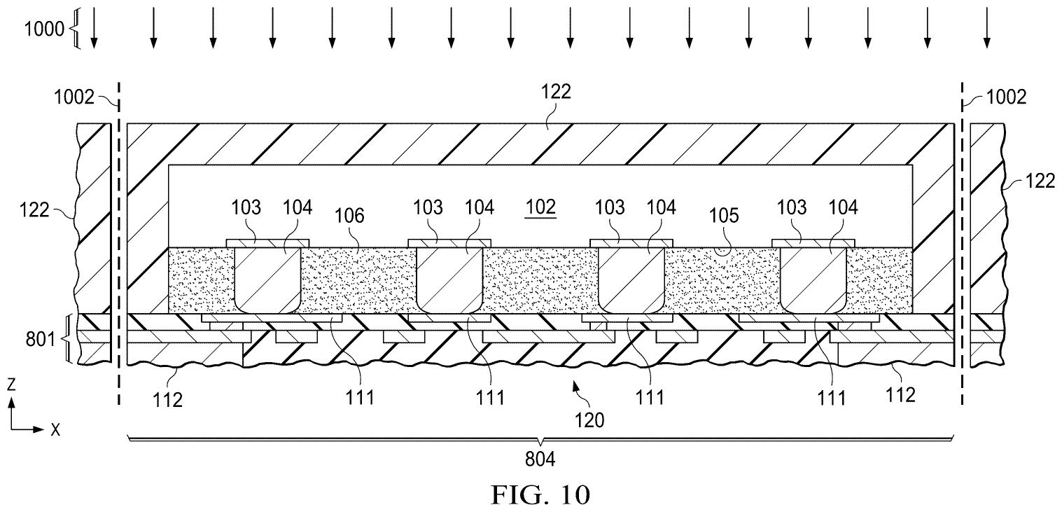

Referring also to FIGS. 2-10, FIG. 2 shows a method 200 of making an electronic device, and FIGS. 3-10 show the example electronic device 120 of FIG. 1B undergoing fabrication processing according to an implementation of the method 200. The method 200 includes wafer level formation of the preformed underfill 106 along a top (e.g., front) side of a processed wafer following stud bump formation and prior to die singulation. This approach facilitates high volume, fully or largely void-free filling between the stud bumps 104 in an economical fast process compared with post-singulation and post-die attach underfill formation by dispensation using the capillary effect, particularly for high stud bump density and small stud bump pitch designs. Moreover, implementations of the method 200 advantageously employ low temperature flip-chip metal-to-metal bonding, such as by ultrasonic welding to help mitigate oxidation and/or strip warpage during fabrication, particularly compared with higher temperature thermal solder reflow operations.

The method 200 begins at 202 in FIG. 2 with stud bump formation on the front side of a processed wafer. FIGS. 3 and 3A show one example, in which a stud bump formation process 300 is performed on a side 105 of a processed wafer 301. The wafer 301 in this example includes one or more circuit components (not shown) in each of an array of rows and columns of prospective die unit areas 304, each of which includes one or more instances of the above described bond pads 103 along the side 105. The process 300 in one example is performed with an automated wirebonding apparatus or system with a nozzle N and a clamp C. A continuous feed of conductive metal bond wire 302 is provided the through an aperture in the nozzle N and automated position control equipment (not shown) translates the nozzle N and the clamp C in three-dimensions to successively form conductive metal stud bumps 104 on respective bond pads 103 along the side 105 of the wafer 301. Any suitable conductive metal bond wire 302 can be used, such as a metal that is or includes copper, aluminum, gold, silver, etc., or combinations or alloys thereof.

In operation in one example, the wirebonding system forms a ball of molten bond wire material slightly below the nozzle N by any suitable means. With the clamp C closed, the system translates the nozzle N downward (along the vertical Z direction) to engage the molten ball with a respective one of the bond pads 103 and to partially collapse the molten ball into a conductive metal stud bump form as shown in FIG. 3. The wirebonding equipment may provide further translation of the nozzle N and the clamp C laterally, such as in a circular motion, in order to form a desired shape of the stud bumps 104, although not a requirement of all possible implementations. The clamp C is then opened, and the nozzle N is translated upward to extend the length of bond wire 302 at the top of the formed stud bump structure 104. The stud bump formation process 300 continues in FIG. 3A with the clamp C again closed, where the wirebonding equipment translates the nozzle N further upward to separate the bond wire 302 from the top of the conductive metal stud bump 104. This or similar processing is performed in each desired location to form multiple instances of the conductive metal stud bump 104 on respective bond pads 103 in each unit area 304 of the processed wafer 301. As shown in FIGS. 3 and 3A, the conductive metal stud bumps 104 have an initial height H1 along the Z direction in the illustrated orientation.

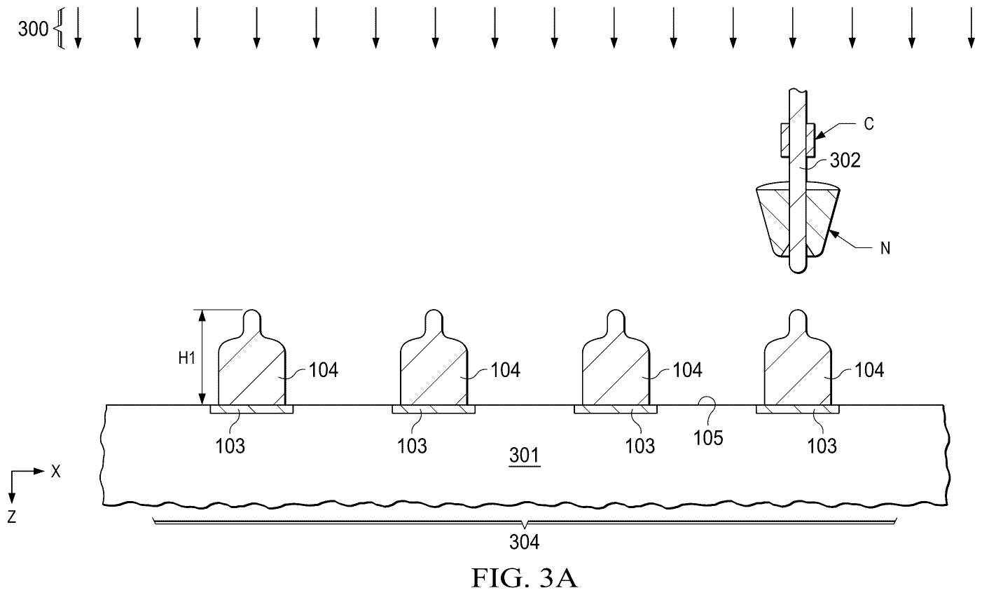

The method 200 continues at 204 in FIG. 2 with formation of the preformed underfill on a portion of the front side 105 of the wafer between the conductive stud bumps 104. FIG. 4 shows one example, in which a process 400 is performed that forms the preformed underfill 106 to an initial or starting thickness T1 along the Z direction, where the preformed underfill thickness T1 is initially greater than the starting height H1 of the conductive metal stud bumps 104. In one example, the underfill formation process 400 includes silk-screening to silkscreen non-conductive epoxy 106 on a portion of the wafer side 105 between the conductive stud bumps 104. In another example, the underfill formation process 400 includes applying a laminate die attach film to the portion of the wafer side 105 between the conductive stud bumps 104. In certain implementations, the underfill material 106 can be formed across the entire side 105 of the processed wafer 301, for example, to facilitate high speed and low cost manufacturing.

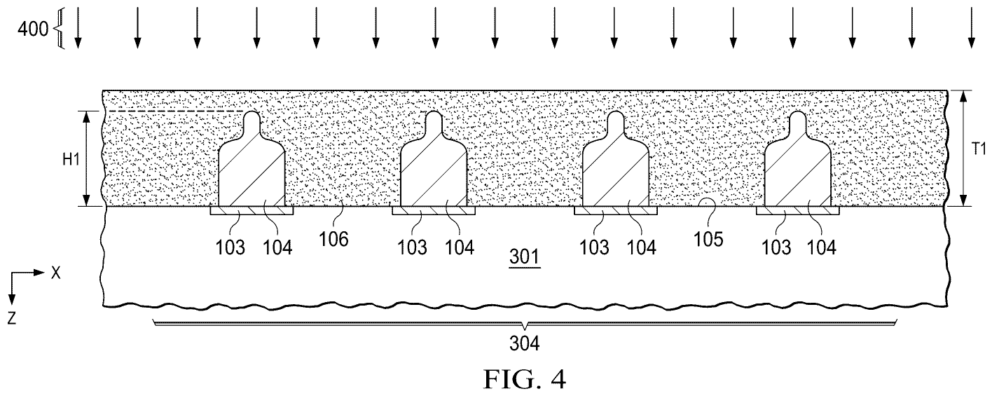

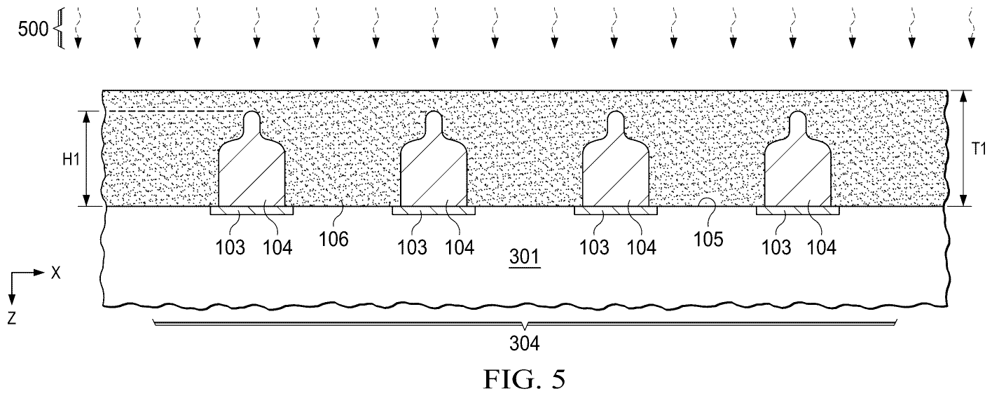

At 206 in FIG. 2, the method 200 continues in one example with optional curing of the preformed underfill 106. FIG. 5 shows one example, in which a thermal curing process 500 is performed that cures the preformed underfill 106. In another implementation, a different form of curing can be used, such as ultraviolet (UV) exposure, etc. In another implementation, the curing step at 206 can be omitted.

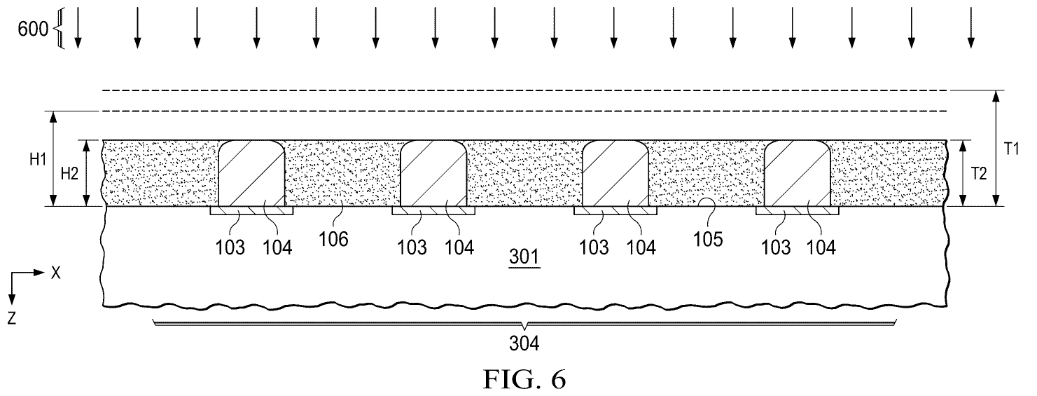

The method 200 continues with grinding at 208 in FIG. 2 to expose the distal ends of the conductive stud bumps 104. FIG. 6 shows one example, in which a grinding process 600 is performed that selectively grinds the top side of the preformed underfill 106. The process 600 exposes the top sides of the conductive stud bumps 104. In one implementation, the grinding process 600 can remove portions of the conductive stud bumps 104 to provide a substantially planar top surface with the conductive stud bumps 104 at a final height H2 which is less than the starting height H1, and the preformed underfill 106 at a final thickness T2 which is less than the starting thickness T1, where T2 is approximately equal to H2 in one example. The processing at 204, 206, and 208 in the illustrated example forms the preformed underfill 106 on a portion of the side 105 of the wafer 301 between the conductive stud bumps 104 and exposes the distal ends of the conductive stud bumps 104 for subsequent metal-to-metal bonding attachment to a lead frame, a single or multilevel package substrate, or directly to a printed circuit board.

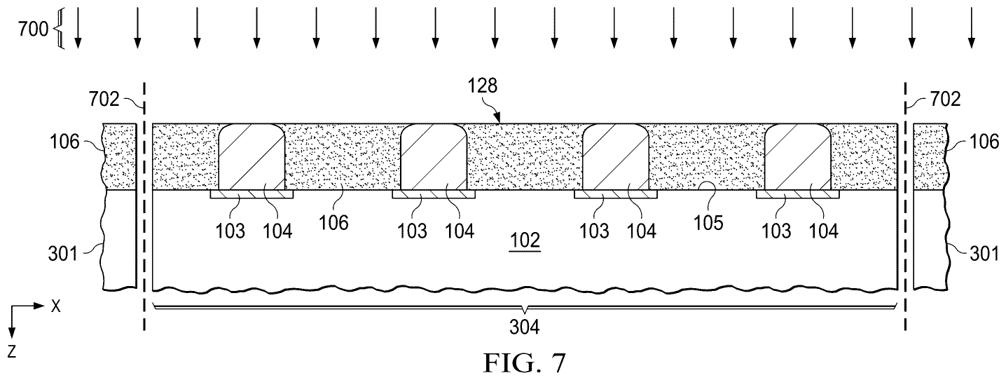

The method 200 continues at 210 in FIG. 2 with die singulation after formation and optional grinding of the preformed underfill 106. FIG. 7 shows one example, in which a die singulation or separation process 700 is performed that separates individual instances of the above described flip-chip die assembly 128 from the starting wafer structure 304 along lines 702. Any suitable die separation process 700 can be used, for example, saw cutting, laser cutting, chemical etching, etc., or combinations thereof. The process 700 separates the semiconductor die 102 from the semiconductor wafer 301, including instances of the conductive stud bumps 104 and a separated corresponding portion of the preformed underfill 106 in each unit area 304 of the starting wafer structure. Following the separation process 700, multiple instances of the flip-chip die assembly 128 can be used as components in a circuit board manufacturing process (not shown) or the flip-ship die assemblies 128 can be further packaged by bonding to a lead frame or substrate.

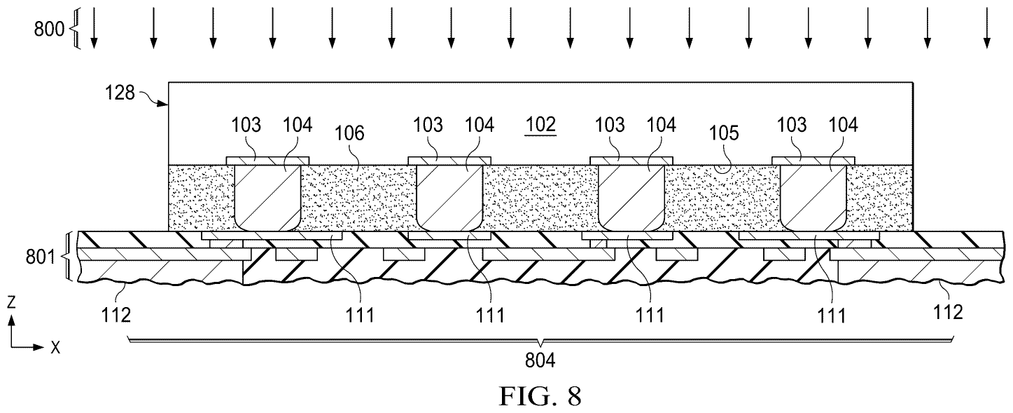

The method 200 continues at 212 in FIG. 2 with flip-chip bonding to a substrate or lead frame in one example. FIG. 8 shows one example, in which a flip-chip bonding process 800 is performed that bonds the distal ends of the conductive stud bumps 104 to a multilevel package substrate panel array structure 801 having rows and columns of unit areas 804, each of which corresponding to a subsequently separated packaged electronic device. The individual unit areas 804 of the substrate panel array structure 801 have conductive features 111. The flip-chip bonding process 800 in one example is or includes a low temperature ultrasonic welding operation using automated ultrasonic welding equipment (not shown), for example, at a temperature of approximately 150-200 degrees C., which is much less than thermal solder reflow processing of solder ball connections.

The process 800 in one example forms metal-to-metal bonds between the distal ends of the conductive stud bumps 104 of an attached flip-chip die assembly 128 engaging respective ones of the conductive features 111 of the substrate panel array 801 in each unit area 804. The ultrasonic welding in this example can include application of controlled amounts of pressure and vibration in one or more directions, such as downward vibration with applied pressure along the Z direction in the illustrated orientation and/or lateral vibration (e.g., in an X-Y plane, not shown) such as circular vibration to melt metal of one or both of the conductive features 111 and the conductive metal stud bumps 104 in order to form metal-to-metal bonds there between in each unit area 804. In other examples, any suitable low temperature direct surface metal-to-metal bonding can be used, for example, a low temperature thermosonic or thermocompression bonding.

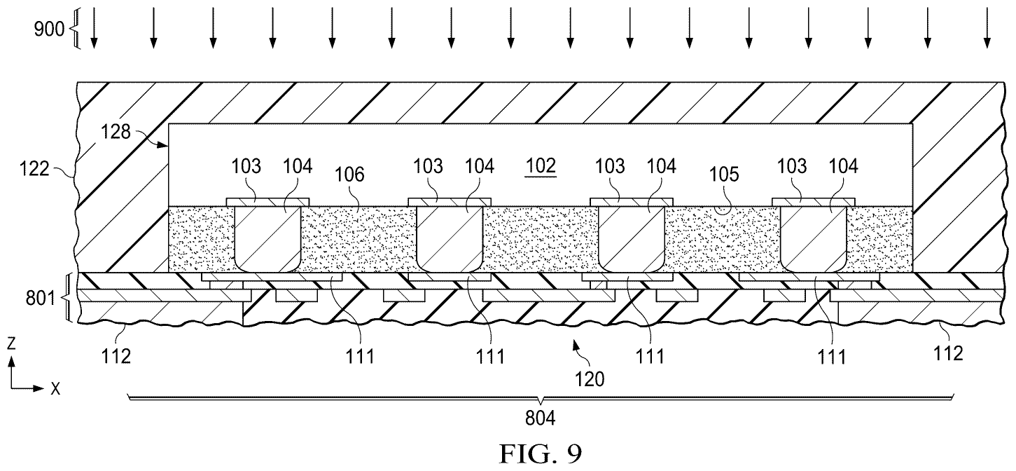

In one example, the method 200 continues at 214 in FIG. 2 with molding. In another example, the molding processing at 214 can be omitted. FIG. 9 shows one example, in which a molding process 900 is performed that forms the molded package structure 122 that encloses the semiconductor die 102 and the preformed underfill 106 and extends along a portion of the top side of the multilevel package substrate panel array 801 in each unit area 804. In one example, a single mold cavity can be used to form the molded package structure 122 that extends along all rows and columns of the panel array structure. In another example, a single mold cavity can be used to construct the molded package structure 122 in each unit area 804 of the array, or a shared mold cavity can be used to create a molded package structure 122 that extends along two or more unit areas 804 of the array structure.

At 216 in FIG. 2, the method 200 continues with package separation. FIG. 9 shows one example, in which a package separation process 1000 is performed that separates individual instances of the above described example electronic device 120 from a corresponding unit area 804 of the starting panel array structure 801 along lines 1002. Any suitable package separation process 1000 can be used, for example, saw cutting, laser cutting, chemical etching, etc., or combinations thereof.

The described example electronic devices and the method 200 provide significant advantages in terms of lowered manufacturing cost, and improved processing time, while providing benefits in terms of reducing or avoiding underfill voids while mitigating or avoiding oxidation and/or panel array warpage during manufacturing. Certain implementations provide low temperature flip-chip metal-to-metal bonding, and the formation of the preformed fill material 106 during wafer processing can greatly increase manufacturing speed and lead to higher units per hour (UPH) in manufacturing electronic devices. Moreover, the preformed underfill 106 provide significant performance advantages in reducing or avoiding voids compared with dispensing underfill fluid using capillary effects, particularly for small pitch stud bumps 104 to facilitate electronic device reduction in miniaturization while increasing circuit density. The enhanced uniformity and good filling performance of the preformed underfill 106 also helps lower stress on stud joints and improved reliability, as well as simplifying manufacturing processing and reducing fabrication cost. This helps ensure robust attachment between the conductive metal stud bumps 104 and a lead frame, substrate, circuit board, etc., for example by ultrasonic bonding. The preformed underfill 106 operates as a shock absorber to mitigate or prevent die cracking from high bonding force during ultrasonic welding or other metal-to-metal bond formation. The described examples and variations thereof can also facilitate low standoff flip-chip designs (e.g., having small or micro-bumps 104), since the height restrictions associated with underfilling for individual attached dies is mitigated by the formation of the preformed underfill 106 at the wafer level. The described examples thus avoid shortcomings associated with conventional underfill dispensing in terms of such height restrictions, as well as limitations to capillary flow effects, etc., particularly for high density, short stud bump designs.

The above examples are merely illustrative of several possible implementations of various aspects of the present disclosure, wherein equivalent alterations and/or modifications will occur to others skilled in the art upon reading and understanding this specification and the annexed drawings. Modifications are possible in the described examples, and other implementations are possible, within the scope of the claims.

What is claimed is:

1. An electronic device, comprising a flip-chip die assembly having a semiconductor die and a preformed underfill, the semiconductor die having conductive bond pads spaced apart from one another along a side of the semiconductor die and conductive stud bumps having proximal ends on respective ones of the conductive bond pads and distal ends extending outward from the side, and the preformed underfill extending on a portion of the side between the conductive stud bumps and exposing the distal ends of the conductive stud bumps.

2. The electronic device of claim 1, further comprising a substrate or lead frame with conductive features, the distal ends of the conductive stud bumps engaging respective ones of the conductive features of the substrate or lead frame.

3. The electronic device of claim 2, wherein the flip-chip die assembly further comprises a molded package structure enclosing a portion of the semiconductor die and a portion of the substrate or lead frame.

4. The electronic device of claim 2, wherein the preformed underfill extends between the side of the semiconductor die and the substrate or lead frame.

5. The electronic device of claim 2, wherein the distal ends of the conductive stud bumps directly contact the respective ones of the conductive features of the substrate or lead frame.

6. The electronic device of claim 2, wherein the distal ends of the conductive stud bumps are bonded to the respective ones of the conductive features of the substrate or lead frame by respective surface metal-to-metal bonds.

7. The electronic device of claim 1, wherein the flip-chip die assembly further comprises a molded package structure enclosing a portion of the semiconductor die.

8. The electronic device of claim 1, wherein the preformed underfill includes a non-conductive die attach adhesive.

9. The electronic device of claim 1, wherein the preformed underfill includes a laminate die attach film.

10. A system, comprising:
a circuit board having a conductive trace; and
an electronic device comprising a flip-chip die assembly and a conductive lead coupled to the conductive trace, the flip-chip die assembly having a semiconductor die and a preformed underfill, the semiconductor die having conductive bond pads spaced apart from one another along a side of the semiconductor die and conductive stud bumps having proximal ends on respective ones of the conductive bond pads and distal ends extending outward from the side, and the preformed underfill extending on a portion of the side between the conductive stud bumps and exposing the distal ends of the conductive stud bumps.

11. The system of claim 10, further comprising a substrate or lead frame with conductive features, the distal ends of the conductive stud bumps engaging respective ones of the conductive features of the substrate or lead frame.

12. The system of claim 11, wherein the preformed underfill extends between the side of the semiconductor die and the substrate or lead frame.

13. The system of claim 11, wherein the distal ends of the conductive stud bumps are bonded to the respective ones of the conductive features of the substrate or lead frame by respective surface metal-to-metal bonds.

14. The system of claim 10, wherein the preformed underfill includes a non-conductive die attach adhesive.

15. The system of claim 10, wherein the preformed underfill includes a laminate die attach film.

16. A method of fabricating an electronic device, the method comprising:
forming conductive stud bumps having proximal ends on respective conductive bond pads along a side of a semiconductor wafer and distal ends extending outward from the side;
forming an underfill on a portion of the side between the conductive stud bumps and exposing the distal ends of the conductive stud bumps;
after forming the underfill, separating a semiconductor die from the semiconductor wafer, the semiconductor die including the conductive stud bumps and the underfill; and
flip-chip bonding the distal ends of the conductive stud bumps to a substrate or lead frame with conductive features, the distal ends of the conductive stud bumps engaging respective ones of the conductive features of the substrate or lead frame.

17. The method of claim 16, wherein forming the underfill comprises silk-screening non-conductive epoxy on the portion of the side between the conductive stud bumps.

18. The method of claim 16, wherein forming the underfill comprises applying a laminate die attach film to the portion of the side between the conductive stud bumps.

19. The method of claim 16, further comprising grinding the underfill to expose the distal ends of the conductive stud bumps.

20. The method of claim 16, wherein flip-chip bonding the distal ends of the conductive stud bumps to the substrate or lead frame comprises performing an ultrasonic welding process (800) to form surface metal-to-metal bonds between the distal ends of the conductive stud bumps to the respective ones of the conductive features of the substrate or lead frame.
